(19) United States
(12) Patent Application Publication
(10) Pub. No.: US 2019/0377036 A1
(43) Pub. Date: Dec. 12, 2019

(54) MAGNETIC SENSOR DEVICE

(71) Applicant: MITSUBISHI ELECTRIC CORPORATION, Chiyoda-ku, Tokyo (JP)

(72) Inventors: Tomokazu OGOMI, Chiyoda-ku (JP); Kenji SHIMOHATA, Chiyoda-ku (JP)

(73) Assignee: MITSUBISHI ELECTRIC CORPORATION, Chiyoda-ku, Tokyo (JP)

(21) Appl. No.: 16/071,331

(22) PCT Filed: May 1, 2017
(86) PCT No.: PCT/JP2017/017117

§ 371 Date: Jul. 19, 2018

(30) Foreign Application Priority Data
May 6, 2016 (JP) 2016-093021

(51) Int. Cl. G01R 33/09; G07D 7/04

(52) U.S. Cl. CPC G01R 33/091; G07D 2207/00; G07D 7/04

(57) ABSTRACT

In a magnetic sensor device, a sheet-like detection object transported along a transport plane is magnetized by a magnetizing magnet that forms a magnetization magnetic field in which magnitude of a magnetic field component parallel to the transport plane is larger than or equal to a saturation magnetic field of a second magnetic body having a second coercivity larger than a first coercivity. The magnetic sensor device includes: a bias magnet that forms a bias magnetic field in which magnitude of a magnetic field component parallel to the plane of the detection object is larger than the first coercivity and less than the second coercivity in the bias magnetic field at the plane of the detection object; and a magnetoresistive effect element chip disposed at the bias magnet and facing the plane of the detection object.

### TECHNICAL FIELD

The present disclosure relates to a magnetic sensor device for distinguishing between two types of magnetic bodies that are included in a sheet-like detection object and have different coercivities.

### BACKGROUND ART

As a countermeasure to prevent counterfeiting of paper currencies or negotiable securities, in recent years paper currency or negotiable securities are issued that use magnetic ink or magnetic bodies of two or more types, the types having different coercivities. Thus there is demand for a magnetic sensor device that distinguishes between magnetic bodies having different coercivities. For example, Patent Literature 1 discloses a magnetic characteristics determination apparatus that discriminates between multiple types of magnetic bodies having different coercivities. The magnetic characteristics determination apparatus of Patent Literature 1 includes a magnetization unit for generating a magnetization magnetic field that includes a first magnetic field region and a second magnetic field region in a transport path, each having a different magnetic field strength and a magnetic field direction, the magnetization unit magnetizing magnetic bodies in different magnetization directions in accordance with the coercivities of the magnetic bodies; and a magnetic sensing unit that causes generation of a bias magnetic field in the transport path in a transport direction-downstream side relative to the magnetization unit, and that detects an amount of magnetism of the magnetic body by detecting a change of the bias magnetic field.

### CITATION LIST

### Patent Literature

Patent Literature 1: Unexamined Japanese Patent Application Kokai Publication No. 2015-201083

### SUMMARY OF INVENTION

### Technical Problem

So that the direction of remanent magnetization differs in accordance with differences in the coercivities, the magnetic characteristics determination apparatus of Patent Literature 1 requires configuration so as to form a magnetization magnetic field that has magnetic field strengths and magnetic field directions that differ according to region. Further, the magnetic characteristic determination apparatus requires accurate setting of the strength and the magnetic force direction tilt of the bias magnetic field relative to the plane of a conveyed paper sheet magnetized by the magnetization magnetic field, and also requires accurate setting of the position and tilt of the magnetic sensor relative to the bias magnetic field. Thus this magnetic sensor device has a problem in that the structure of the magnetic characteristics determination apparatus is extremely complex.

In consideration of circumstances such as those described above, an objective of the present invention is to simplify the strength and arrangement of the magnetization magnetic field and the bias magnetic field, and to simplify the structure for arrangement of the magnetic sensor, so as to distinguish between two types of magnetic bodies having different coercivities.

### Solution to Problem

In order to attain the aforementioned objective, a magnetic sensor device according to an aspect of the present disclosure is a magnetic sensor device for sensing a sheet-like detection object magnetized by a magnetizing magnet that forms a magnetization magnetic field in a transport plane, magnitude of a magnetic field component parallel to the transport plane in the transport plane of the magnetization magnetic field being larger than or equal to a saturation magnetic field of a second magnetic body having a second coercivity larger than a first coercivity. The magnetic sensor device includes:

a bias magnet to form a bias magnetic field having a magnetic force direction of a center of a magnetic flux that intersects a plane of the detection object magnetized by the magnetizing magnet transported along the transport plane, wherein magnitude of a magnetic field component parallel to the plane of the detection object in the bias magnetic field occurring in the plane of the detection object is larger than the first coercivity, and is less than the second coercivity; and

a magnetoresistive effect element disposed at the bias magnet and facing the plane of the detection object.

### Advantageous Effects of Invention

According to the present disclosure, the magnitude of the magnetic field component parallel to the transport plane at the center of the magnetization magnetic field in the transport plane is larger than or equal to the saturation magnetic field of the second magnetic body, the magnitude of the magnetic field component parallel to the transport plane at the center of the bias magnetic field occurring in the transport plane is larger than the first coercivity and is smaller than the second coercivity, and the magnetoresistive effect element is arranged at a surface of the bias magnetic facing the transport plane, thereby simplifying the intensities and arrangements of the magnetization magnetic field and the bias magnetic field, and simplifying the structure for arrangement of the magnetic sensor.

### BRIEF DESCRIPTION OF DRAWINGS

FIG. 1 is a configuration drawing of a magnetic sensor device according to Embodiment 1 of the present disclosure;

FIG. 2 is a drawing illustrating a magnetic force vector of a bias magnetic field applied to a magnetoresistive effect element in the magnetic sensor device according to Embodiment 1;

FIG. 3 is a drawing illustrating a magnetization state of a magnetic body included in a detection object after passing through a magnetization magnetic field in the magnetic sensor device according to Embodiment 1;

FIG. 4A is a drawing illustrating a magnetization state of the magnetic body when the magnetic body enters the bias magnetic field, in a case in which a coercivity of the magnetic body included in the detection object is smaller than the bias magnetic field strength, for the magnetic sensor device according to Embodiment 1;

FIG. 4B is a drawing illustrating a magnetization state of the magnetic body when the magnetic body is in a center of the bias magnetic field, in the case in which the coercivity of the magnetic body is smaller than the bias magnetic field strength, for the magnetic sensor device according to Embodiment 1;

FIG. 4C is a drawing illustrating a magnetization state of the magnetic body when the magnetic body leaves the bias magnetic field, in the case in which the coercivity of the magnetic body is smaller than the bias magnetic field strength, for the magnetic sensor device according to Embodiment 1;

FIG. 5A is a drawing illustrating a magnetic field applied to the magnetoresistive effect element when the magnetic body enters the bias magnetic field, in the case in which the coercivity of the magnetic body included in the detection object is smaller than the bias magnetic field strength, for the magnetic sensor device according to Embodiment 1;

FIG. 5B is a drawing illustrating a magnetic field applied to the magnetoresistive effect element when the magnetic body is in the center of the bias magnetic field, in the case in which the coercivity of the magnetic body is smaller than the bias magnetic field strength, for the magnetic sensor device according to Embodiment 1;

FIG. 5C is a drawing illustrating a magnetic field applied to the magnetoresistive effect element when the magnetic body leaves the bias magnetic field, in the case in which the coercivity of the magnetic body is smaller than the bias magnetic field strength, for the magnetic sensor device according to Embodiment 1;

FIG. 6 is a drawing illustrating an example of an output waveform of a magnetic sensor in the case in which the coercivity of the magnetic body included in the detection object is smaller than the bias magnetic field strength, for the magnetic sensor device according to Embodiment 1;

FIG. 7A is a drawing illustrating a magnetization state of the magnetic body when the magnetic body enters the bias magnetic field, in a case in which a coercivity of the magnetic body included in the detection object is larger than the bias magnetic field strength, for the magnetic sensor device according to Embodiment 1;

FIG. 7B is a drawing illustrating a magnetization state of the magnetic body when the magnetic body is in the center of the bias magnetic field, in the case in which the coercivity of the magnetic body is larger than the bias magnetic field strength, for the magnetic sensor device according to Embodiment 1;

FIG. 7C is a drawing illustrating a magnetization state of the magnetic body when the magnetic body leaves the bias magnetic field, in the case in which the coercivity of the magnetic body is larger than the bias magnetic field strength, for the magnetic sensor device according to Embodiment 1;

FIG. 8A is a drawing illustrating a magnetic field applied to the magnetoresistive effect element when the magnetic body enters the bias magnetic field, in the case in which the coercivity of the magnetic body included in the detection object is larger than the bias magnetic field strength, for the magnetic sensor device according to Embodiment 1;

FIG. 8B is a drawing illustrating a magnetic field applied to the magnetoresistive effect element when the magnetic body passes directly above the magnetoresistive effect element, in the case in which the coercivity of the magnetic body is larger than the bias magnetic field strength, for the magnetic sensor device according to Embodiment 1;

FIG. 8C is a drawing illustrating a magnetic field applied to the magnetoresistive effect element when the magnetic body leaves the bias magnetic field, in the case in which the coercivity of the magnetic body is larger than the bias magnetic field strength, for the magnetic sensor device according to Embodiment 1;

FIG. 9 is a drawing illustrating an example of an output wavefonn of a magnetic sensor in the case in which the coercivity of the magnetic body included in the detection object is larger than the bias magnetic field strength, for the magnetic sensor device according to Embodiment 1;

FIG. 10 is a configuration drawing of a magnetic sensor device according to Embodiment 2 of the present disclosure;

FIG. 11 is a configuration drawing of a magnetic sensor device according to Embodiment 3 of the present disclosure;

FIG. 12 is a configuration drawing of a magnetic sensor device according to Embodiment 4 of the present disclosure;

FIG. 13 is a configuration drawing of a magnetic sensor device according to Embodiment 5 of the present disclosure;

FIG. 14 is a configuration drawing of a magnetic sensor device according to Embodiment 6 of the present disclosure;

FIG. 15 is a configuration drawing of a magnetic sensor device according to Embodiment 7 of the present disclosure; and

FIG. 16 is a configuration drawing of a magnetic sensor device according to Embodiment 8 of the present disclosure.

### DESCRIPTION OF EMBODIMENTS

Embodiments of the present description are described below in detail with reference to drawings. In the drawings, components that are the same or equivalent are assigned the same reference signs. Further, in all of the embodiments of the present disclosure, a transport direction of a detection object, that is, a transverse direction (sub-scanning direction) of a coercivity-identifying magnetic sensor device is defined to be an X direction; a longitudinal direction (main-scanning direction) of the coercivity-identifying magnetic sensor device perpendicular to the transport direction of the detection object is defined to be a Y direction; and a direction (perpendicular to the transport direction) perpendicular to the transverse direction (transport direction, sub-scanning direction) and the longitudinal direction (main-scanning direction) of the coercivity-identifying magnetic sensor device is defined to be a Z direction.

### Embodiment 1

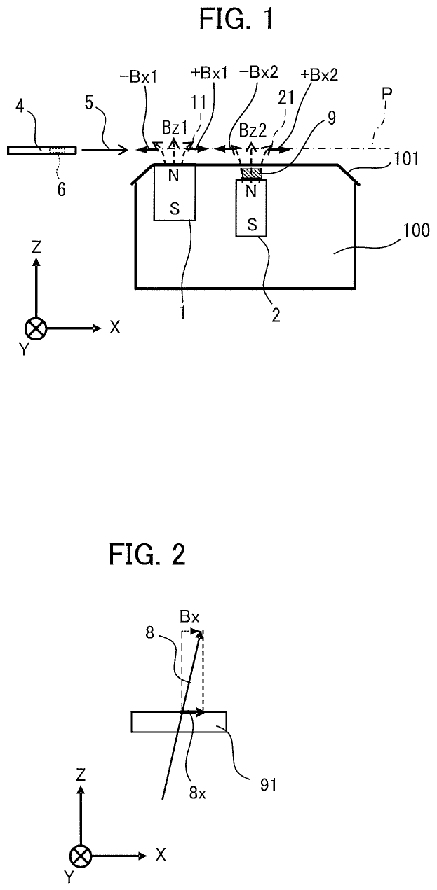

FIG. 1 is a configuration drawing of a magnetic sensor device according to Embodiment 1 of the present disclosure. FIG. 1 is a cross-sectional drawing perpendicular to the main-scanning direction. The magnetic sensor device is equipped with a magnetizing magnet 1, a bias magnet 2, and a magnetoresistive effect element chip 9 within a housing 100. Further, a shield cover 101 is provided on a transport plane-side of the housing 100. The magnetizing magnet 1 and the bias magnet 2 are arranged facing a transport plane P for transport of a sheet-like detection object 4 that includes a magnetic body 6. The detection object 4 is transported along the transport direction 5 on the transport plane P.

The magnetizing magnet 1 has magnetic poles directed in mutually different directions perpendicular to the transport plane P, and forms a magnetization magnetic field 11 in which a magnetic force direction of the center of the magnetic flux intersects the transport plane P. The bias magnet 2 has magnetic poles directed in mutually different directions perpendicular to the transport plane P, and forms a bias magnetic field 21 in which a magnetic force direction of the center of the magnetic flux intersects the transport plane P. The bias magnet 2 is arranged in the transport direction 5 downstream from the magnetizing magnet 1. In Embodiment 1, the magnetic force directions of the centers of the magnetic flux of the magnetization magnetic field 11 and the bias magnetic field 21 are perpendicular to the transport plane P.

Due to the magnetization magnetic field 11, the magnetizing magnet 1 magnetizes the magnetic body 6 included in the detection object 4. Due to the bias magnetic field 21, the bias magnet 2 applies a magnetic bias to the magnetic body 6 of the detection object 4, and simultaneously applies a magnetic bias to the magnetoresistive effect element chip 9.

An amplification IC for amplification of an output from the magnetoresistive effect element chip 9, a circuit board for receiving the output from and applying voltage to the magnetoresistive effect element chip 9, a magnetic yoke for stabilization of magnetic force of the magnets, or the like are provided as elements included in the magnetic sensor, although these elements are omitted from FIG. 1.

The magnetoresistive effect element chip 9 of the magnetic sensor device according to Embodiment 1 is arranged at the detection object 4 side of the bias magnet 2. The magnetic poles of the magnetizing magnet 1 and the bias magnet 2 generate the magnetization magnetic field 11 and the bias magnetic field 12, respectively, with the N pole taken to be at the transport plane P side, and the S pole taken to be at the opposite side. In the transport plane P, for the magnetization magnetic field 11 formed by the magnetizing magnet 1, a component perpendicular to the transport plane P is defined to be a magnetization Z-direction magnetic field Bz1, a component parallel to the transport plane P and opposite to the transport direction is defined to be a magnetization negative-X-direction magnetic field −Bx1, and a component parallel to the transport plane P and in the transport direction is defined to be a magnetization positive-X-direction magnetic field +Bx1; and for the bias magnetic field 21 formed by the bias magnet 2, a component perpendicular to the transport plane P is defined to be a bias Z-direction magnetic field Bz2, a component parallel to the transport plane P and opposite to the transport direction is defined to be a bias negative-X-direction magnetic field −Bx2, and a component parallel to the transport plane P and in the transport direction is defined to be a bias positive-X-direction magnetic field +Bx2. Although the minus symbol “−” is appended to the reference sign for a negative-direction magnetic field, the components of the magnetic fields are all absolute values.

The magnetizing magnet 1 of the magnetic sensor device applies the magnetization magnetic field 11 to the magnetic body 6 arranged on the detection object 4, and magnetizes the magnetic body 6. The bias magnet 2 applies the bias magnetic field 21 to the magnetoresistive effect element chip 9 and to the magnetic body 6 arranged on the detection object 4.

FIG. 2 is a drawing illustrating a magnetic force vector of the bias magnetic field applied to a magnetoresistive effect element, in the magnetic sensor device according to Embodiment 1. The magnetoresistive effect element 91 of the magnetoresistive effect element chip 9 is separated slightly in the positive-X direction from the transport-direction center of the bias magnet 2, and as illustrated in FIG. 2, the magnetic bias vector 8 tilts from the Z direction (perpendicular to the transport plane P) somewhat in the X direction (transport direction). A transport direction component 8x of this magnetic bias vector 8 acts as the bias magnetic field of the magnetoresistive effect element 91, and due to a change in magnitude of the transport direction component 8x, the magnetic body 6 arranged on the detection object 4 can be detected by a change in output. When there is no magnetic body 6, the transport direction component 8x of the magnetic bias vector 8 is equal to the transport direction component Bx of the bias magnetic field 21 formed by the bias magnet 2.

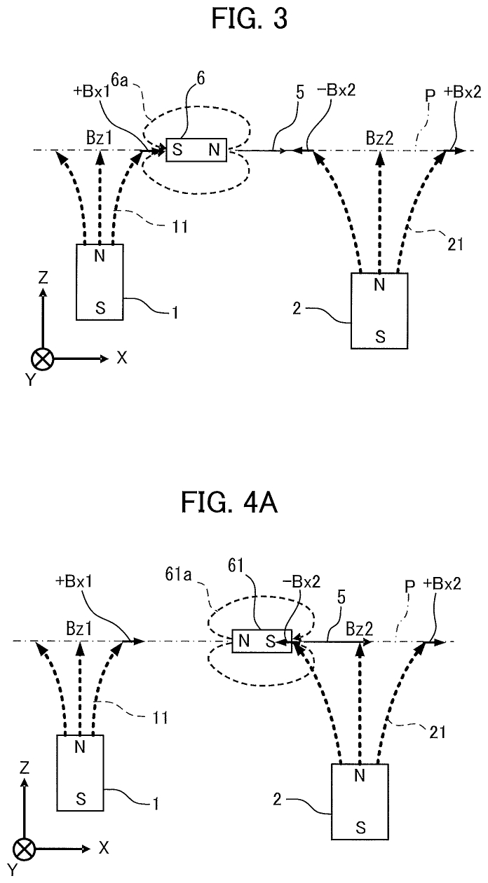

FIG. 3 is a drawing illustrating a magnetization state of the magnetic body included in the detection object after passing through the magnetization magnetic field in the magnetic sensor device according to Embodiment 1. A minimum magnetic field for causing saturation magnetization of the magnetic body 6 is defined to be a saturation magnetic field Bs6. The magnetized magnetic body 6 forms a magnetic field 6a. In the transport plane P, the magnetization positive-X-direction field +Bx1 that is the component in the transport direction and parallel to the transport plane P of the magnetization magnetic field 11 produced by the magnetizing magnet 1 is configured so as to be larger than the saturation magnetic field Bs6 of the magnetic body 6. The magnetic body 6 arranged on the detection object 4, after passing through the magnetization magnetic field 11, has remanent magnetism such that the transport direction-upstream side is the S pole and forms the magnetic field 6a illustrated in FIG. 3.

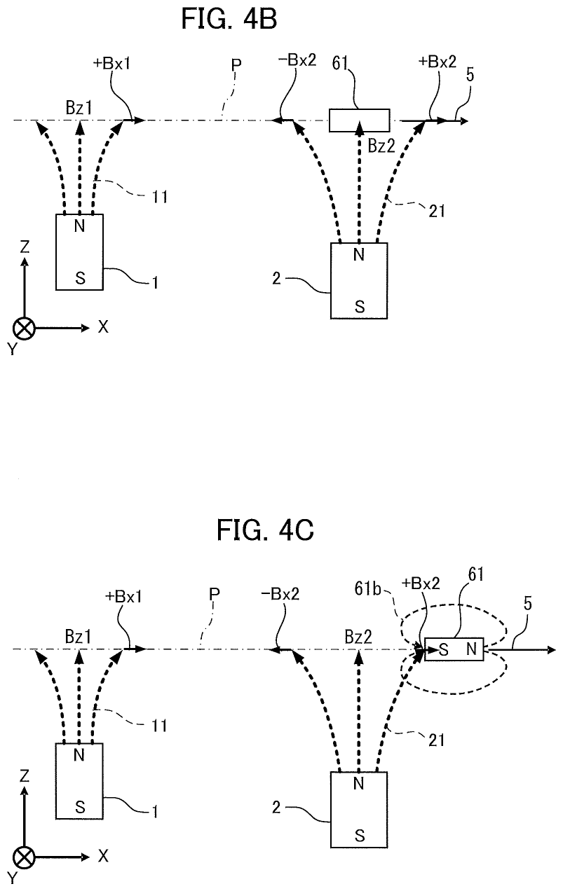

Magnetization of the magnetic body 6 by the bias magnet 2 is described next using FIG. 4A to FIG. 4C in the case in which the coercivity Bc6 of the magnetic body 6 is smaller than the bias negative-X-direction magnetic field −Bx2 that is the component that is parallel to the transport plane P and is directed opposite to the transport direction. The sign of the coercivity Bc6 of the magnetic body 6 is positive in the transport direction, and is negative opposite to the transport direction. The magnetic body 6 for which the coercivity Bc6 is smaller than the bias negative-X-direction magnetic field −Bx2 of the bias magnetic field 21 occurring in the transport plane P is taken to be a magnetic body 61. A coercivity Bc61 of the magnetic body 61 is smaller than the bias negative-X-direction magnetic field −Bx2 occurring in the transport plane P. The coercivity Bc61 of the magnetic body 61 is smaller than the bias negative-X-direction magnetic field −Bx2 occurring in the transport plane P, the magnetic body 61 is magnetized again by the bias magnetic field 21.

FIG. 4A is a drawing illustrating the magnetization state of the magnetic body when the magnetic body enters the bias magnetic field, in a case in which a coercivity of the magnetic body included in the detection object is smaller than the bias magnetic field strength, for the magnetic sensor device according to Embodiment 1. When the magnetic body 61 arranged on the detection object 4 enters the bias magnetic field 21, as illustrated in FIG. 4A, the magnetic body 61 is magnetized by the bias magnetic field 21 such that the transport direction-downstream side becomes the S pole, and the magnetic body 61 forms the magnetic field 61a of FIG. 4A.

FIG. 4B is a drawing illustrating the magnetization state of the magnetic body when the magnetic body is in a center of the bias magnetic field, in the case in which the coercivity of the magnetic body is smaller than the bias magnetic field strength, for the magnetic sensor device according to Embodiment 1. Upon the magnetic body 61 coming to the center of the bias magnetic field 21, the line of magnetic force of the center of the magnetic flux of the bias magnetic field 21 is perpendicular to the transport plane P, and thus as illustrated in FIG. 4B, due to the bias magnetic field 21 not having an X-direction component, the X-direction component of magnetization of the magnetic body 61 ceases to exist.

FIG. 4C is a drawing illustrating the magnetization state of the magnetic body when the magnetic body leaves the bias magnetic field, in the case in which the coercivity of the magnetic body is smaller than the bias magnetic field strength, for the magnetic sensor device according to Embodiment 1. When the magnetic body 61 leaves the bias magnetic field 21, as illustrated in FIG. 4C, the magnetic body 61 is magnetized by the bias magnetic field 21 such that the transport direction-upstream side becomes the S pole, and the magnetic body 61 forms the magnetic field 61b of FIG. 4C.

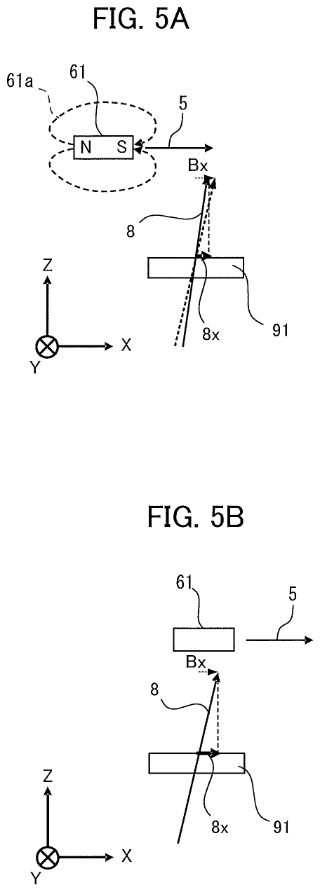

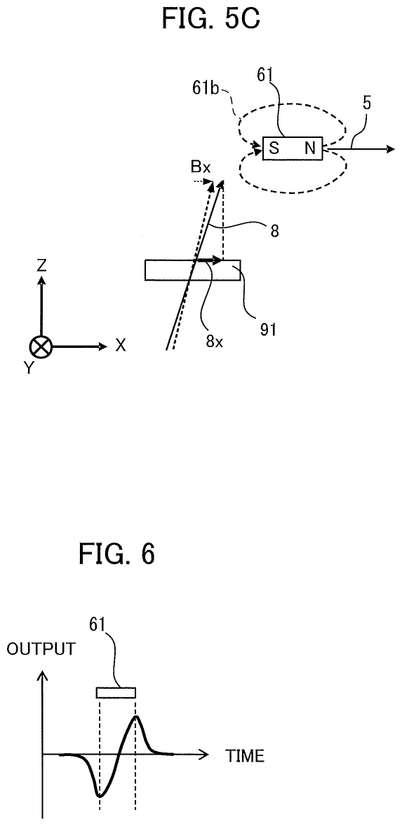

The operation of detecting the magnetic body 61 by the magnetoresistive effect element 91 when the magnetic body 61 passes through the bias magnetic field 21 in the transport plane P is described in detail with reference to FIG. 5A to FIG. 5C. In FIG. 5A to FIG. 5C, a composite vector formed from the bias magnetic field and the magnetic field 61a of the magnetic body 61 at the magnetoresistive effect element 91 is indicated by the solid-line magnetic bias vector 8. The dashed line arrow crossing the magnetic bias vector 8 in FIG. 5A to FIG. 5C indicates the magnetic bias vector 8 in the case illustrated in FIG. 2 in which there is no magnetic body 61.

When the magnetic body 61 enters the bias magnetic field 21 and the bias magnetic field strength passing through the magnetic body 61 is larger than the coercivity Bc61, the X-direction magnetization of the magnetic body 61 reverses as illustrated in FIG. 5A. As a result, due to action of the magnetic field 61a formed by the magnetic body 61, the transport direction component 8x of the magnetic bias occurring at the magnetoresistive effect element 91 is smaller than the transport direction component Bx of the magnetic bias in the case in which there is no magnetic body 61.

When the magnetic body 61 comes to the center of the bias magnetic field 21, due to the bias magnetic field passing through the magnetic body 61 not having an X-direction component, the X-direction component of magnetization of the magnetic body 61 ceases to exist. As a result, as illustrated in FIG. 5B, the transport direction component 8x of the magnetic bias occurring at the magnetoresistive effect element 91 is the same as that of the state illustrated in FIG. 2. Further, when the magnetic body 61 leaves the bias magnetic field 21, the magnetic body 61 is magnetized in the X direction by the bias magnetic field 21, and thus remanent magnetization is formed that is directed opposite to that of magnetization of the magnetic body 61 that occurs when entering the bias magnetic field 21 and being magnetized again. As a result, as illustrated in FIG. 5C, due to the action of the magnetic field 61b formed by the magnetic body 61, the transport direction component 8x of the magnetic bias occurring at the magnetoresistive effect element 91 is larger than the transport direction component Bx of the magnetic bias in the case in which there is no magnetic body.

As illustrated in FIG. 4A to FIG. 4C, in the case in which the coercivity Bc61 of the magnetic body 61 is smaller than the bias negative-X-direction magnetic field −Bx2 that is a component directly opposite to the transport direction and parallel to the transport plane P of the bias magnetic field 21 occurring in the transport plane P, the direction of magnetization of the magnetic body 61 reverses in the X direction in accordance with movement of the magnetic body 61 through the transport plane P in the transport direction 5. Then in accordance with such reversal, as illustrated in FIG. 5A to 5C, the magnitude of the transport direction component 8x of the magnetic bias occurring at the magnetoresistive effect element 91 changes and straddles the magnitude of the transport direction component Bx in the case in which there is no magnetic body. FIG. 6 is a drawing illustrating an example of an output waveform of the magnetic sensor in the case in which the coercivity of the magnetic body included in the detection object is smaller than the bias magnetic field strength, for the magnetic sensor device according to Embodiment 1. In accordance with movement of the magnetic body 61 in the transport direction 5 in the transport plane P, resistance of the magnetoresistive effect element 91 sensing the X-direction component magnetism changes, output such as that illustrated in FIG. 6 is obtained, and the magnetic body 61 arranged on the detection object 4 can be sensed. As illustrated in FIG. 6, when the coercivity Bc61 of the magnetic body 61 is smaller than the bias-negative-X-direction magnetic field −Bx2 occurring at the transport plane P, an edge detection output is obtained such that the output at peak outputs reverse in sign at the front-rear edges of the magnetic body 61.

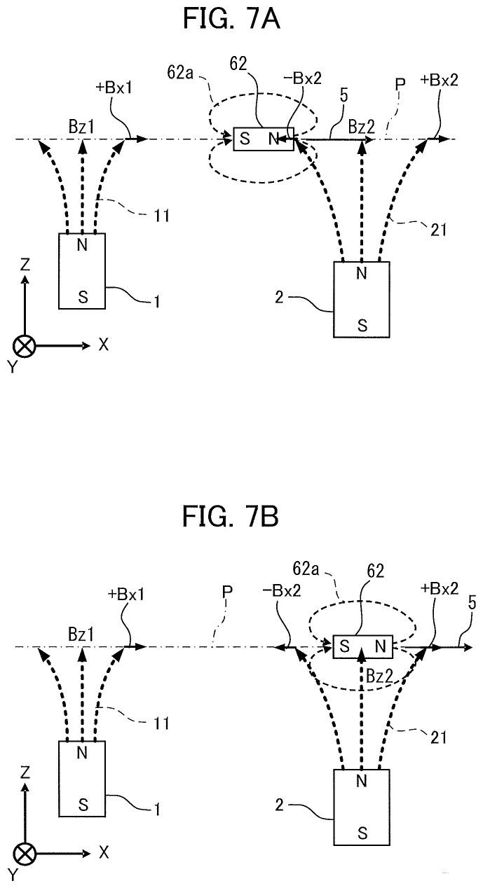

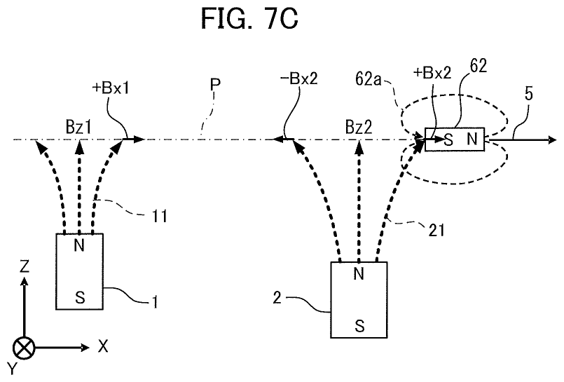

Magnetization of the magnetic body 6 by the bias magnet 2 is described next with reference to FIG. 7A to FIG. 7C, in the case in which the coercivity Bc6 of the magnetic body 6 is larger than the bias negative-X-direction magnetic field −Bx2 that is the component directly opposite to the transport direction and parallel to the transport plane P of the bias magnetic field 21 occurring in the transport plane P. The magnetic body 6 for which the coercivity Bc6 is larger than the bias negative-X-direction magnetic field −Bx2 occurring in the transport plane P is taken to be a magnetic body 62. A coercivity Bc62 of the magnetic body 62 is larger than the bias negative-X-direction magnetic field −Bx2 occurring in the transport plane P. The coercivity Bc62 of the magnetic body 62 is larger than the bias negative-X-direction magnetic field −Bx2 occurring in the transport plane P, and thus the magnetic body 62 is not magnetized again by the bias magnetic field 21.

Even though the magnetic body 62 arranged on the detection object 4 passes through the bias magnetic field 21, as illustrated in FIG. 7A to FIG. 7C, the magnetic body 62 is not magnetized again by the bias magnetic field 21, and thus the direction of the remanent magnetization after leaving the magnetization magnetic field 11 is maintained. As illustrated in FIG. 7A to FIG. 7C, in a detection range of the magnetoresistive effect element 91 in Embodiment 1, the magnetic body 62 maintains a magnetic field 62a in which the upstream side of the magnetic body 62 in the transport direction 5 is the S pole.

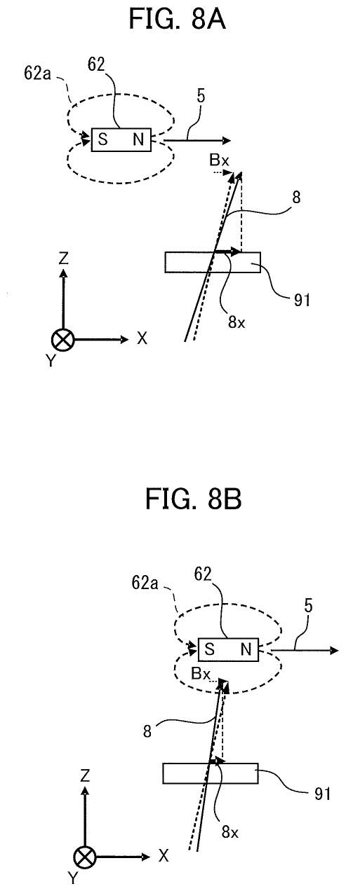

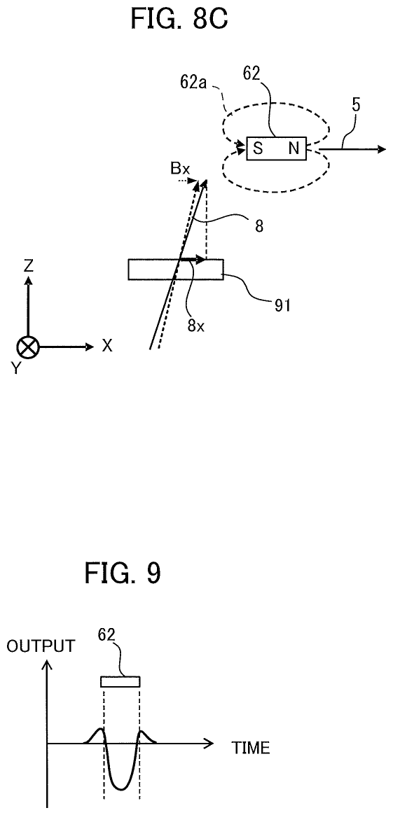

The operation of detection of the magnetic body 62 by the magnetoresistive effect element 91 is described in detail with reference to FIG. 8A to FIG. 8C when the magnetic body 62 passes through the bias magnetic field 21 in the transport plane P. In FIG. 8A to FIG. 8C, a composite vector formed at the magnetoresistive effect element 91 from the bias magnetic field and the magnetic field 62a of the magnetic body 62 is indicated by the solid-line magnetic bias vector 8. The dashed line arrow crossing the magnetic bias vector 8 in FIG. 8A to FIG. 8C indicates the positions of the magnetic bias vector 8 in the case, as illustrated in FIG. 2, in which there is no magnetic body 62.

Even though the magnetic body 62 enters the bias magnetic field 21, the magnetic body 62 maintains the direction of magnetization, and thus as illustrated in FIG. 8A, the X-direction magnetization of the magnetic body 62 matches the direction of the transport direction component of the magnetic bias occurring at the magnetoresistive effect element 91. The magnetic field 62a formed by the magnetic body 62 acts such that the line of magnetic force passing through the magnetoresistive effect element 91 is directed away in the transport direction 5. As a result, the transport direction component 8x of the magnetic bias occurring at the magnetoresistive effect element 91 is larger than the transport direction component Bx of the magnetic bias in the case in which there is no magnetic body 62.

When the magnetic body 62 passes directly above the magnetoresistive effect element 91, as illustrated in FIG. 8B, the magnetic field 62a of the magnetic body 62 acts in a direction that counteracts the transport direction component Bx of the magnetic bias in the case in which there is no magnetic body 62. As a result, the transport direction component 8x of the magnetic bias occurring at the magnetoresistive effect element 91 is smaller than the transport direction component Bx of the magnetic bias in the case in which there is no magnetic body 62.

When the magnetic body 62 leaves the bias magnetic field 21, the magnetic field 62a of the magnetic body 62 acts in a direction that attracts the line of magnetic force of the bias magnetic field 21. As a result as illustrated in FIG. 8C, due to the action of the magnetic field 62a formed by the magnetic body 62, the transport direction component 8x of the magnetic bias occurring at the magnetoresistive effect element 91 is larger than the transport direction component Bx of the bias magnetic field 21 in the case in which there is no magnetic body.

FIG. 9 is a drawing illustrating an example of an output waveform of a magnetic sensor in the case in which the coercivity of the magnetic body included in the detection object is larger than the bias magnetic field strength, for the magnetic sensor device according to Embodiment 1. As illustrated in FIG. 7A to FIG. 7C, the direction of X-direction magnetization of the magnetic body 62 does not change during passage of the magnetic body 62 through the bias magnetic field 21, and thus as illustrated in FIG. 8a to FIG. 8C, the transport direction component 8x of the magnetic bias occurring at the magnetoresistive effect element 91 changes, in turn, from larger, to smaller, to larger than the transport direction component Bx of the magnetic bias in the case in which there is no magnetic body 62. As a result, resistance of the magnetoresistive effect element 91 sensing the X-direction component changes in accordance with movement of the magnetic body 62 in the transport direction 5 in the transport plane P, an output such as that illustrated in FIG. 9 is obtained, and the magnetic body 62 arranged on the detection object 4 can be sensed. In the case in which the coercivity Bc62 of the magnetic body 62 is larger than the bias negative-X-direction magnetic field −Bx2 occurring in the transport plane P, as illustrated in FIG. 9, a pattern of detection output is obtained in which, during passage of the magnetic body 62 above the magnetoresistive effect element 91, the polarities of the peak outputs reverse upon entering and upon leaving the bias magnetic field 21.

As understood upon comparison between FIG. 6 and FIG. 9, according to the magnetic sensor device of Embodiment 1, different detection output waveforms are obtained for the cases in which the coercivity Bc6 of the magnetic body 6 is smaller or is larger than the bias negative-X-direction magnetic field −Bx2 occurring in the transport plane P, thereby enabling distinguishing between two types of magnetic bodies that have different coercivities.

Using the principle described above, the output of the magnetic body 61 having the coercivity Bc61 can have the pattern detection output as illustrated in FIG. 6, and the output of the magnetic body 62 having the coercivity Bc62 can have the pattern detection output as illustrated in FIG. 9. That is, when the sheet-like detection object 4 includes at least one of the first magnetic body 61 having the first coercivity Bc61 or the second magnetic body 62 having the second coercivity Bc62 larger than the first coercivity Bc61, the magnetization magnetic field 11 formed by the magnetizing magnet 1 is set such that, magnitude of the magnetization positive-X-direction magnetic field +Bx1 that is the transport-direction component parallel to the transport plane P is larger than or equal to the saturation magnetic field Bs62 of the second magnetic body 62, and the bias magnetic field 21 formed by the bias magnet 2 arranged downstream from the magnetizing magnet 1 in the transport direction 5 is set such that the magnitude of the bias negative-X-direction magnetic field −Bx2 that is the component parallel to the transport plane P and directed opposite to the transport direction is larger than the first coercivity Bc61 and is smaller than the second coercivity Bc62. Due to setting in such a manner, identification is possible of the magnetic body 61 having the first coercivity Bc61 and the second magnetic body 62 having the second coercivity Bc62 larger than the first coercivity Bc61.

In Embodiment 1, the magnetization magnetic field 11 formed by the magnetizing magnet 1 may be any magnetic field that causes the magnetization positive-X-direction magnetic field +Bx1 in the transport plane P is larger than the saturation magnetic field of the magnetic body 62 that has the larger coercivity. Further, the bias magnetic field 21 formed by the bias magnet 2 may be any magnetic field that causes the bias negative-X-direction magnetic field −Bx2 in the transport plane P is larger than the coercivity Bc61 of the magnetic body 61 that has the smaller coercivity and is smaller than the coercivity Bc62 of the magnetic body 62 that has the larger coercivity. Further, at the transport plane P side of the bias magnet 2, the magnetoresistive effect element 91 may be arranged at a position somewhat separated in the transport direction from the transport- direction center of the face of the bias magnet 2 facing the transport plane P.

The magnetic characteristics determination apparatus of Patent Literature 1 requires configuration to form a magnetization magnetic field having magnetic field strengths and a magnetic field directions that differ in accordance with regions so that the direction of remanent magnetization differs in accordance with changes in the coercivity. Further, accurate seeing is required for the intensity and tilt of the magnetic force direction of the bias magnetic field relative to the surface of the transported paper sheet magnetized by the magnetization magnetic field and the location and tilt of the magnetic sensor relative to the bias magnetic field. In comparison, in the magnetic sensor device of Embodiment 1, the degrees of accuracy are relaxed for the positions and magnetic force of the magnetizing magnet 1 and the bias magnet 2 and the position and tilt of the magnetoresistive effect element 91. Further, tilting of the direction of the line of magnetic force of the bias magnetic field 21 relative to the transport plane P is not required, and the transport direction overall length of the magnetic sensor device can be reduced.

In accordance with the magnetic sensor device of Embodiment 1, the magnetizing magnet 1 and the bias magnet 2 can be arranged at the same side with respect to the transport plane P, and size of the coercivity-identifying magnetic sensor can be reduced. Neither the magnetizing magnet 1 nor the bias magnet 2 of the magnetic sensor device of Embodiment 1 requires a complicated magnet morphology, and thus the magnetic sensor can include a simple magnetic circuit.

Further, although the magnetic poles of the magnetizing magnet 1 in Embodiment 1 are described by taking the transport plane P side to be the N pole, the transport plane P side may be made the S pole, and a similar effect is obtained except just that orientation is opposite to the direction of remanent magnetization of the magnetic body 6 by the magnetization magnetic field 11. The magnetic poles of the bias magnet 2 may be oriented such that the transport plane P side is made the S pole, and a similar effect is obtained except just that the positive-negative direction detection output of the magnetic body 6 becomes opposite.

Further, the directions of the magnetic poles of the magnetizing magnet 1 and the bias magnet 2 may have different polarizations with respect to the transport plane side. For example, the transport plane P side of the magnetizing magnet 1 may be made the S pole, the transport plane P side of the bias magnet 2 may be made the N pole, and a similar effect is obtained except just that the positive-negative direction of the detection output in accordance with the coercivity Bch of the magnetic body 6 becomes opposite.

Although the configuration of the magnetoresistive effect element 91 in Embodiment 1 is not specified in Embodiment 1, the used configuration may be a half-bridge configuration that positions two magnetic resistive elements 91 in series and outputs a center point potential, a full-bridge configuration that positions four magnetoresistive effect elements 91, or a single-unit configuration.

In Embodiment 1, the general case is described in which the coercivity Bc61 of the magnetic body 61 is larger than the coercivity Bc62 of the magnetic body 62. In Embodiment 1, the magnetic body 62 can be considered to be a hard magnetic body that has an extremely high coercivity Bc62. In this case, the detection output of the magnetoresistive effect element 91 results in a pattern such as that illustrated in FIG. 9, and thus the magnetic sensor device of Embodiment 1 is capable of detection even when the detection object 4 includes only the hard magnetic body as a magnetic body.

### Embodiment 2

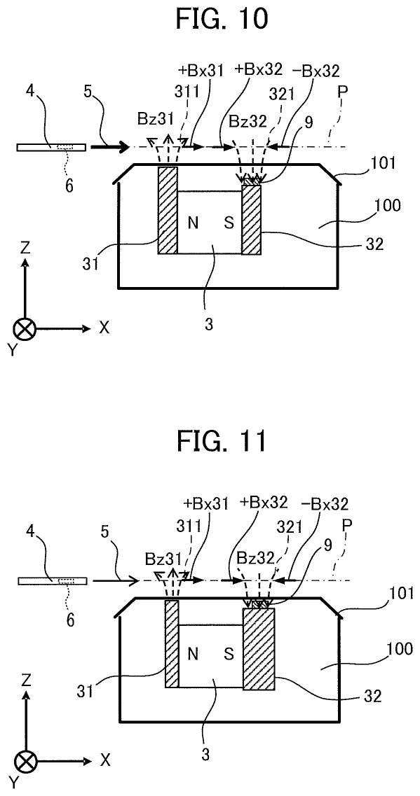

FIG. 10 is a configuration drawing of a magnetic sensor device according to Embodiment 2 of the present disclosure. FIG. 10 is a cross-sectional drawing perpendicular to the main-scanning direction. Instead of using the magnetizing magnet 1 and the bias magnet 2 indicated in Embodiment 1, Embodiment 2 uses a single center magnet 3, a magnetization yoke 31 that is a first yoke, and a biasing yoke 32 that is a second yoke. The center magnet 3 used in Embodiment 2 has magnetic poles that are mutually different in a direction parallel to the transport direction 5 of the detection object 4. In FIG. 10, the transport direction 5 upstream side of the center magnet 3 is the N pole, and the downstream side is the S pole. Lengths in the Y direction, which is the main-scanning direction, of the center magnet 3, the magnetization yoke 31, and the biasing yoke 32 are the same, and are larger than the reading width of the magnetic sensor device.

The magnetization yoke 31 is arranged at the transport direction 5 upstream side of the center magnet 3, and the biasing yoke 32 is arranged at the transport direction 5 downstream side of the center magnet 3. The magnetoresistive effect element chip 9 is arranged at a surface on the biasing yoke 32 facing the transport plane P. The other configuration is similar to that of Embodiment 1. Although omitted from the drawing, components generally included in a magnetic sensor are included, such as an amplification IC for amplifying the output from the magnetoresistive effect element chip 9, a circuit board for applying electrical power to and receiving output from the magnetoresistive effect element chip 9, and a magnetic yoke for stabilizing magnetic force of the magnet.

The magnetic flux flowing out from the transport direction 5 upstream side N-pole of the center magnet 3 enters the magnetization yoke 31, is emitted to space from the periphery of the magnetization yoke 31 as viewed in the transport direction 5, enters the biasing yoke 32 from the periphery of the biasing yoke 32 as viewed in the transport direction 5, and from the biasing yoke 32 reaches the S pole of the transport direction 5 downstream side of the center magnet 3. The magnetic flux emitted from the center magnet 3 and returning to the center magnet 3 is concentrated mainly in the magnetization yoke 31 and the biasing yoke 32. The magnetization yoke 31 and the biasing yoke 32 are temporary magnets that are magnetized by the center magnet 3.

Within the magnetic flux emitted into space from the magnetization yoke 31, the magnetic flux directed in the transport plane P forms a magnetization magnetic field 311. Further, within the magnetic flux entering the biasing yoke 32, the magnetic flux directed toward the biasing yoke 32 from the transport plane P forms a bias magnetic field 321. The magnetization yoke 31 as a temporary magnet forms the magnetizing magnet. Further, the biasing yoke 32 as a temporary magnet forms the bias magnet. The magnetization yoke 31 applies the magnetization magnetic field 311 to the magnetic body 6 arranged on the detection object 4 and magnetizes the magnetic body 6. The biasing yoke 32 applies the bias magnetic field 321 to the magnetic body 6 arranged on the detection object 4 and to the magnetoresistive effect element chip 9.

The magnetization magnetic field 311 and the bias magnetic field 321 are regarded as uniform in the Y direction (main scan direction) lengths of the center magnet 3, the magnetization yoke 31, and the biasing yoke 32.

In the transport plane P, for the magnetization magnetic field 311 formed by the magnetization yoke 31, a component perpendicular to the transport plane P is defined to be a magnetization Z-direction magnetic field Bz31, a component parallel to the transport plane P and opposite to the transport direction is defined to be a magnetization negative-X-direction magnetic field −Bx31, and a component parallel to the transport plane P and in the transport direction is defined to be a magnetization positive-X-direction magnetic field +Bx31; and for the bias magnetic field 321 formed by the biasing yoke 32, a component perpendicular to the transport plane P is defined to be a bias Z-direction magnetic field Bz32, a component parallel to the transport plane P and in the transport direction is defined to be a bias positive-X-direction magnetic field +Bx32, and a component parallel to the transport plane P and opposite to the transport direction is defined to be a bias negative-X-direction magnetic field −Bx32 In the same manner as in Embodiment 1, the coercivity Bc62 of the magnetic body 62 is assumed to be larger than the coercivity Bc61 of the magnetic body 61. Size of the magnetization positive-X-direction magnetic field +Bx31 is larger than or equal to the saturation magnetic field Bs62 of the magnetic body 62 that has the large coercivity Bc6. Further, size of the bias positive-X-direction magnetic field +Bx32 is larger than the coercivity Bc61 of the magnetic body 61 and is less than the coercivity Bc62 of the magnetic body 62.

In order to set Bx31>Bs62, and to set Bc62>Bx32>Bc61, the transport plane P side surface of the magnetization yoke 31 may be arranged closer to the transport plane P than the transport plane P side surface of the biasing yoke 32. The magnetic flux emitted from the magnetization yoke 31 and the magnetic flux entering the biasing yoke 32 spread widely with increased distance from the respective surfaces, and thus magnetic flux densities decline with distance, and the magnetic field strength proportional to the magnetic flux density also decreases. Thus by adjusting the magnetic force of the center magnet 3 and the distances of the transport plane P side surfaces of the magnetization yoke 31 and the biasing yoke 32 from the transport plane P, the configuration satisfies the relationships Bx31>Bs62 and Bc62>Bx32>Bc61. The coercivity Bc62 is generally smaller than the saturation magnetic field Bs62, and thus distance to the transport plane P from the surface of the magnetization yoke 31 facing the transport plane P is made smaller than the distance to the transport plane P from the surface of the biasing yoke 32 facing the transport plane P.

Although the positive-negative signs of the detection output is opposite in accordance with the coercivity Bc6 of the magnetic body 6 for the magnetic sensor device according to Embodiment 2, the magnetic sensor device according to Embodiment 2 can distinguish between the magnetic body 61 and the magnetic body 62 in the same manner as in Embodiment 1. Due to configuration of Embodiment 2 in this manner, a single magnet can be used. Further, arrangement of the N pole and the S pole of the center magnet 3 is not limited to the directions illustrated in FIG. 10, and these directions can be reversed.

### Embodiment 3

FIG. 11 is a configuration drawing of a magnetic sensor device according to Embodiment 3 of the present disclosure. FIG. 11 is a cross-sectional drawing perpendicular to the main-scanning direction. Instead of the magnetizing magnet 1 and the bias magnet 2 indicated in Embodiment 1, a single center magnet 3, a magnetization yoke 31 that is a first yoke, and a biasing yoke 32 that is a second yoke are used in Embodiment 3. Embodiment 3 differs from Embodiment 2 in that size of the surface of the magnetization yoke 31 facing the transport plane P is different from the size of the surface of the biasing yoke 32 facing the transport plane P. The configuration is otherwise similar to that of Embodiment 2.

Due to mutual repulsion between the lines of magnetic force, respective magnetic flux densities can be regarded as uniform at the surfaces of the magnetization yoke 31 and the biasing yoke 32 facing the transport plane P. The magnetic flux emitted from the surface of the magnetization yoke 31 facing the transport plane P can be regarded to be the same as the magnetic flux entering the surface of the biasing yoke 32 facing the transport plane P. Since the magnetic fluxes are the same, if the magnetic flux density in cross section is uniform, then the magnetic flux density is inversely proportional to the cross-sectional area. Thus by setting the transport direction 5 length of the surface of the biasing yoke 32 (second yoke) facing the transport plane P to be longer than the length in the transport direction 5 of the surface of the magnetization yoke 31 (first yoke) facing the transport plane P, the magnetization positive-X-direction magnetic field +Bx31 can be made larger than the bias positive-X-direction magnetic field +Bx32.

Further, in a manner similar to Embodiment 2, the distance to the transport plane P from the surface of the magnetization yoke 31 facing the transport plane P can be set smaller than the distance to the transport plane P from the surface of the biasing yoke 32 facing the transport plane P.

Thus by adjusting the magnetic force of the center magnet 3 and the transport direction 5 lengths of the transport plane P side surfaces of the magnetization yoke 31 and the biasing yoke 32, the configuration of Embodiment 3 satisfies the relationships Bx31>Bs62 and Bc62>Bx32>Bc61. Although the positive-negative sign directions are opposite for the detection outputs of the coercivity Bch of the magnetic bodies 6 for the magnetic sensor device according to Embodiment 3, the magnetic sensor device according to Embodiment 3 operates similarly to that of Embodiment 1 and can distinguish between the magnetic body 61 and the magnetic body 62. Further, the arrangement of the N pole and the S pole of the center magnet 3 is not limited to the directions of FIG. 11, and these directions may be reversed.

### Embodiment 4

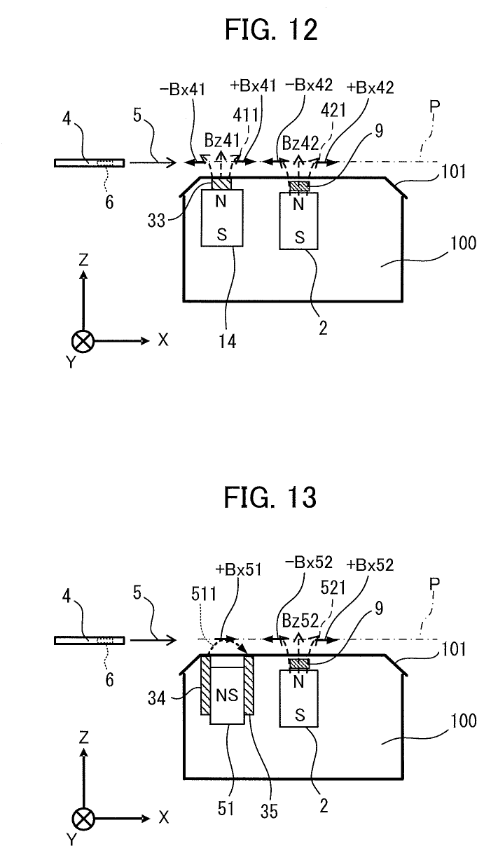

FIG. 12 is a configuration drawing of a magnetic sensor device according to Embodiment 4 of the present disclosure. FIG. 12 is a cross-sectional drawing perpendicular to the main-scanning direction. In Embodiment 4, the magnetizing magnet 1 illustrated in Embodiment 1 includes a magnetization magnet 14 and a magnetism-collecting yoke 33 arranged at a transport plane P side surface of the magnetization magnet 14. The configuration is otherwise similar to that of Embodiment 1.

In the transport plane P in Embodiment 4, for the magnetization magnetic field 411 formed by the magnetization magnet 14 and the magnetism-collecting yoke 33, a component perpendicular to the transport plane P is defined to be a magnetization Z-direction magnetic field Bz41, a component parallel to the transport plane P and opposite to the transport direction is defined to be a magnetization negative-X-direction magnetic field −Bx41, and a component parallel to the transport plane P and in the transport direction is defined to be a magnetization positive-X-direction magnetic field +Bx41; and for a bias magnetic field 421 formed by the bias magnet 2, a component perpendicular to the transport plane P is defined to be a bias Z-direction magnetic field Bz42, a component parallel to the transport plane P and opposite to the transport direction is defined to be a bias negative-X-direction magnetic field −Bx42, and a component parallel to the transport plane P and in the transport direction is defined to be a bias positive-X-direction magnetic field +Bx42.

In Embodiment 4, the magnetic force of the bias magnet 2 and the transport direction 5 lengths of the transport plane P-side surfaces of the magnetization magnet 14 and the magnetism-collecting yoke 33 are adjusted such that configuration satisfies the relationships +Bx41>Bs62 and Bc62>−Bx42>Bc61.

The transport direction length of the magnetism-collecting yoke 33 is shorter than the transport direction length of the magnetization magnet 14. Due to configuration in this manner, the main magnetic flux of the magnetization magnet 14 is collected in the range of the magnetism-collecting yoke 33. If the magnetization magnet 14 is the same as the magnetization magnet 1, then the magnetization magnetic field 411 is larger than the magnetization magnetic field 11 of Embodiment 1. Thus in the case of generation of a magnetization magnetic field 411 that is the same as the magnetization magnetic field 11 of Embodiment 1, size of the magnetization magnet 14 can be reduced below the size of the magnetizing magnet 1.

Further, the magnetic poles of the magnetization magnet 14 in Embodiment 4 are described by setting the N pole at the transport plane P side, the S pole may be set at the transport plane P side as described in Embodiment 1. Even though the arrangement of the magnetic poles of the bias magnet 2 sets the S pole at the transport plane P side, the obtained effect is similar except for just reversal of the positive-negative direction of the detection output of the magnetic body 6.

Further, the directions of the magnetic poles of the magnetization magnet 14 and the bias magnet 2 may have different polarizations with respect to the transport plane side. For example, even if the transport plane P side of the magnetization magnet 14 is set to the S pole, and the transport plane P side of the bias magnet 2 is set to the N pole, a similar effect is obtained except just that positive-negative direction sign of the detection output due to the coercivity Bch of the magnetic body 6 is reversed.

### Embodiment 5

FIG. 13 is a configuration drawing of a magnetic sensor device according to Embodiment 5 of the present disclosure. FIG. 13 is a cross-sectional drawing perpendicular to the main-scanning direction. In Embodiment 5, the magnetizing magnet 1 indicated in Embodiment 1 is configured in the same manner except for configuration as a magnetization magnet 51 for causing magnetization in a direction parallel to the transport direction 5 and an upstream-side yoke 34 and a downstream-side yoke 35 arranged at both sides of the magnetization magnet 51. Due to this configuration, between the upstream-side yoke 34 and the downstream-side yoke 35 in the transport plane P, a magnetization magnetic field 511 is formed in a direction parallel to the transport direction.

In the transport plane P in Embodiment 5, for the magnetization magnetic field 511 formed by the magnetization magnet 51, the upstream-side yoke 34, and the downstream-side yoke 35, a component parallel to the transport plane P and in the transport direction is defined to be a magnetization positive-X-direction magnetic field +Bx51, and for the bias magnetic field 521 formed by the bias magnet 2, a component perpendicular to the transport plane P is defined to be a bias-Z-direction field Bz52, a component parallel to the transport plane P and opposite to the transport direction is defined to be a bias-negative-X-direction magnetic field −Bx52, and a component parallel to the transport plane P and in the transport direction is defined to be a bias-positive-X-direction magnetic field +Bx52.

In Embodiment 5, the magnetization magnet 51, the upstream-side yoke 34, and the downstream-side yoke 35 are adjusted such that the configuration satisfies the relationships +Bx51>Bs62 and Bc62>−Bx52>Bc61.

In the case of the configuration of Embodiment 5, the magnetization positive-X-direction magnetic field +Bx51 is the main magnetic flux. Further, the magnetic flux of the magnetization magnet 51 is concentrated at the upstream-side yoke 34 and the downstream-side yoke 35, and thus a large magnetization positive-X-direction magnetic field +Bx51 can be formed even when using a small magnet.

Further, although the magnetic poles of the magnetization magnet 51 in Embodiment 5 are described by setting the transport direction upstream side as the N pole, the transport direction upstream side may be set to the S pole in a manner similar to that described for Embodiment 1. The magnetic poles of the bias magnet 2 may be oriented such that the transport plane P side is made the S pole, and a similar effect is obtained except just that the positive-negative direction detection output of the magnetic body 6 becomes opposite.

### Embodiment 6

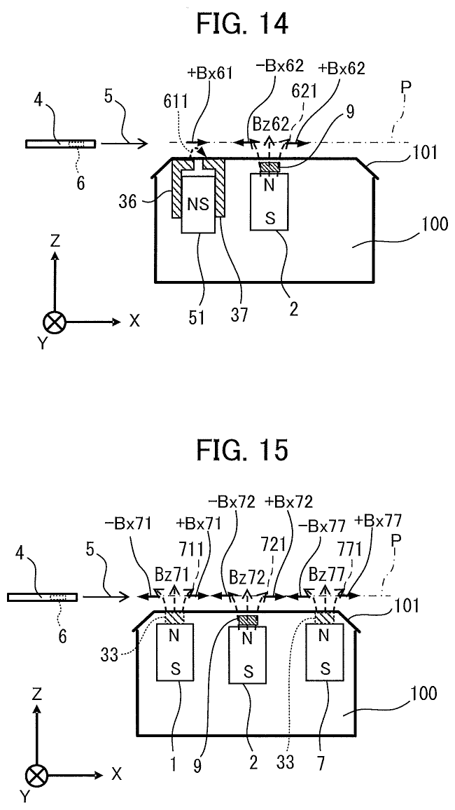

FIG. 14 is a configuration drawing of a magnetic sensor device according to Embodiment 6 of the present disclosure. FIG. 14 is a cross-sectional drawing perpendicular to the main-scanning direction. In Embodiment 6, the upstream-side yoke 36 and the downstream-side yoke 37 change to L shapes from the configuration of Embodiment 5. The configuration otherwise is the same as that of Embodiment 5. At the magnetization magnet 51 transport plane P side, proximate portions, longer than the transport direction length of the magnetization magnet 51, are formed in the upstream-side yoke 36 and the downstream-side yoke 37 so that the proximate portions project and approach one another.

In the transport plane P in Embodiment 6, for the magnetization magnetic field 611 formed by the magnetization magnet 51, the upstream-side yoke 36, and the downstream-side yoke 37, a component parallel to the transport plane P and in the transport direction is defined to be a magnetization positive-X-direction magnetic field +Bx61; and for the bias magnetic field 621 formed by the bias magnet 2, a component perpendicular to the transport plane P is defined to be a bias-Z-direction field Bz62, a component parallel to the transport plane P and opposite to the transport direction is defined to be a bias-negative-X-direction magnetic field −Bx62, and a component parallel to the transport plane P and in the transport direction is defined to be a bias-positive-X-direction magnetic field +Bx62.

In Embodiment 6, the magnetization magnet 51, the upstream-side yoke 36, and the downstream-side yoke 37 are adjusted such that the configuration satisfies the relationships +Bx61>Bs62 and Bc62>−Bx62>Bc61.

In accordance with the configuration of Embodiment 6, in the transport plane P, the magnetization magnetic field 611 parallel to the transport direction is formed between the upstream-side yoke 36 and the downstream-side yoke 37. In the case of this configuration, the magnetization positive-X-direction magnetic field +Bx61 that is the transport direction component parallel to the transport plane P is the main magnetic flux. Further, the magnetic flux of the magnetization magnet 51 is concentrated in the upstream-side yoke 36 and the downstream-side yoke 37 and the magnetic poles are close to each other due to the forming of the proximate portions, and thus a further large magnetization positive-X-direction magnetic field +Bx61 can be formed even when using a small magnet. In the same manner as in Embodiment 5, either polarity may be used for the directions of the magnetic poles of the magnetization magnet 51 and the bias magnet 2.

### Embodiment 7

FIG. 15 is a configuration drawing of a magnetic sensor device according to Embodiment 7 of the present disclosure. FIG. 15 is a cross-sectional drawing perpendicular to the main-scanning direction. The configuration of Embodiment 7 arranges a reverse-transport magnetizing magnet 7, working in the same manner as the magnetizing magnet 1 indicated in Embodiment 1, at the transport direction downstream side of the bias magnet 2. In a plane perpendicular to the transport direction 5 and passing through the center of the bias magnet 2, the reverse-transport magnetizing magnet 7 is preferably arranged symmetrically with respect to the magnetizing magnet 1.

In the transport plane P in Embodiment 7, for the magnetization magnetic field 711 formed by the magnetizing magnet 1, a component perpendicular to the transport plane P is defined to be a magnetization Z-direction magnetic field Bz71, a component parallel to the transport plane P and opposite to the transport direction is defined to be a magnetization negative-X-direction magnetic field −Bx71, and a component parallel to the transport plane P and in the transport direction is defined to be a magnetization positive-X-direction magnetic field +Bx71; and for the bias magnetic field 721 formed by the bias magnet 2, a component perpendicular to the transport plane P is defined to be a bias Z-direction magnetic field Bz72, a component parallel to the transport plane P and opposite to the transport direction is defined to be a bias negative-X-direction magnetic field −Bz72, and a component parallel to the transport plane P and in the transport direction is defined to be a bias positive-X-direction magnetic field +Bx72. Further, for the magnetization magnetic field 771 formed by the reverse-transport magnetizing magnet 7, a component perpendicular to the transport plane P is defined to be a magnetization Z-direction magnetic field Bz77, a component parallel to the transport plane P and opposite to the transport direction is defined to be a magnetization negative-X-direction magnetic field −Bz77, and a component parallel to the transport plane P and in the transport direction is defined to be a magnetization positive-X-direction magnetic field +Bx77.

In Embodiment 7, the magnetic force strength of the bias magnet 2 and the magnetic force strength of the magnetizing magnet 1 are configured so as to satisfy the relationships +Bx71>Bs62 and Bc62>−Bx72>Bc61. Further, magnetic force strength of the reverse-transport magnetizing magnet 7 is configured to satisfy the relationship −Bx77>Bs62. If the magnetizing magnet 1 and the reverse-transport magnetizing magnet 7 have magnetic force strengths of the same size, then −Bx77>Bs62.

Due to the configuration of Embodiment 7, in a magnetic sensor device requiring bi-directional transport and capable of transporting the detection object 4 in a direction opposite to the transport direction 5, the coercivity can be identified for either direction of transport. In this case, due to the magnetic bias vector 8 applied to the magnetoresistive effect element 91 being tilted in the transport direction 5, the direction of the magnetic bias vector 8 relative to the reverse transport direction is opposite to the direction of the magnetic bias vector 8 relative to the transport direction 5, and if the bias magnetic field when there are no magnetic bodies 61 and 62 is taken to be standard, the obtained output pattern in the reverse transport direction is the same as that of FIG. 6 and FIG. 9 with positive-negative reversed.

In Embodiment 7, at least one of the magnetizing magnet 1 or the reverse-transport magnetizing magnet 7 can be configured as the magnetization magnet 14 and the magnetism-collecting yoke 33 of Embodiment 4. In FIG. 15, the case in which the magnetism-collecting yoke 33 is provided is illustrated by dashed lines. In this case, the magnetizing magnet 1 and the reverse-transport magnetizing magnet 7 can each be replaced by the magnetization magnet 14.

Further, the directions of the magnetic poles of the magnetizing magnet 1 and the bias magnet 2 may be the reverse of those of FIG. 15, or the directions may be mutually opposite one another, as described with reference to Embodiment 1. Further, the direction of the magnetic poles of the reverse-transport magnetizing magnet 7 may be the reverse of the direction of the magnetic poles of the magnetizing magnet 1.

### Embodiment 8

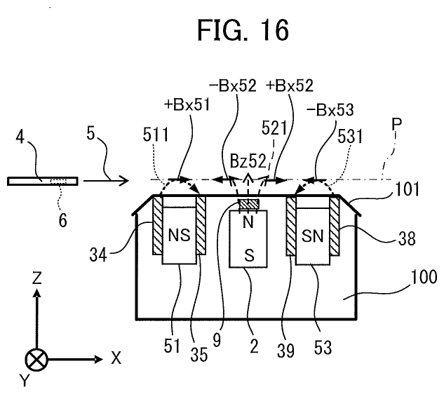

FIG. 16 is a configuration drawing of a magnetic sensor device according to Embodiment 8 of the present disclosure. FIG. 16 is a cross-sectional drawing perpendicular to the main-scanning direction. In the configuration of Embodiment 8, the magnetization magnet 51, the upstream-side yoke 34, and the downstream-side yoke 35 indicated in Embodiment 5 are also arranged in the transport direction downstream side of the bias magnet 2. The magnetization magnet 51, the upstream-side yoke 34 and the downstream-side yoke 35 are arranged symmetrically in the plane perpendicular to the transport direction 5 with respect to a magnetization magnet 53, an upstream-side yoke 38 and a downstream-side yoke 39. The magnetization magnet 51, the upstream-side yoke 34 and the downstream-side yoke 35 are preferably symmetrical with respect to the magnetization magnet 53, the upstream-side yoke 38 and the downstream-side yoke 39 in the plane perpendicular to the transport direction 5 and passing through the center of the bias magnet 2.

In the transport plane P in Embodiment 8, for the magnetization magnetic field 511 formed by the magnetization magnet 51, the upstream-side yoke 34, and the downstream-side yoke 35, a component parallel to the transport plane P and in the transport direction is defined to be a magnetization positive-X-direction magnetic field +Bx51; and for the bias magnetic field 521 formed by the bias magnet 2, a component perpendicular to the transport plane P is defined to be a bias Z-direction magnetic field Bz52, a component parallel to the transport plane P and opposite to the transport direction is defined to be a bias negative-X-direction magnetic field −Bz52, and a component parallel to the transport plane P and in the transport direction is defined to be a bias positive-X-direction magnetic field +Bx52. Further, for the magnetization magnetic field 531 formed by the magnetization magnet 53, the upstream-side yoke 38, and the downstream-side yoke 39, a component parallel to the transport plane P and opposite to the transport direction is defined to be a magnetization negative-X-direction magnetic field −Bx53.

In the configuration of Embodiment 8, the magnetization magnet 51, the upstream-side yoke 34, and the downstream-side yoke 35 are adjusted so as to satisfy the relationships +Bx51>Bs62 and Bc62>−Bx52>Bc61. Further, the magnetization magnet 53, the upstream-side yoke 38, and the downstream-side yoke 39 are adjusted so as to satisfy the relationship −Bx53>Bs62. If the magnetization magnet 51, the upstream-side yoke 34, and the downstream-side yoke 35 have the same size of magnetic force as the magnetization magnet 53, the upstream-side yoke 38, and the downstream-side yoke 39, then −Bx53>Bs62.

Due to the configuration of Embodiment 8, in a magnetic sensor device requiring bi-directional transport and capable of transporting the detection object 4 in a direction opposite to the transport direction 5, the coercivity can be identified for either direction of transport. In this case, due to the magnetic bias vector 8 applied to the magnetoresistive effect element 91 being tilted in the transport direction 5, the direction of the magnetic bias vector 8 relative to the reverse transport direction is opposite to the direction of the magnetic bias vector 8 relative to the transport direction 5, and if the bias magnetic field in the absence of magnetic bodies 61 and 62 is taken to be standard, the obtained output patterns in the reverse transport direction are the same as those of FIG. 6 and FIG. 9 with positive-negative reversed.

In Embodiment 8, the upstream-side yoke 34 and the downstream-side yoke 35, or the upstream-side yoke 38 and the downstream-side yoke 39, can be configured as in the upstream-side yoke 36 and the downstream-side yoke 37 of Embodiment 6. In this configuration, in addition to the configuration of Embodiment 6, components that are the same as the magnetization magnet 51, the upstream-side yoke 36, and the downstream-side yoke 37 are arranged symmetrically with respect to the plane perpendicular to the transport direction 5 and passing through the center of the bias magnet 2. In this configuration, an effect is obtained that is the same as that of the configuration of FIG. 16.

Further, although the magnetic poles of the magnetization magnet 51 in Embodiment 8 are described by taking the transport direction 5 upstream side to be the N pole, in a manner similar to that described in Embodiment 1, the transport direction 5 upstream side may be taken to be the S pole. Also for the bias magnet 2, even if the magnetic poles are arranged by taking the transport plane P side to be the S pole, an effect is obtained similarly except just that the positive-negative directions of the detection output of the magnetic body 6 are reversed. Thus the direction of the magnetic poles of the magnetization magnet 53 may be reversely-oriented and asymmetric relative to the magnetization magnet 51 in the plane perpendicular to the transport direction 5, that is to say, the directions of the magnetic poles may have the same orientations in the transport direction 5.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Patent Application No. 2016-093021, filed on May 6, 2016, the entire disclosure of which is incorporated by reference herein.

### REFERENCE SIGNS LIST

1 Magnetizing magnet
2 Bias magnet
3 Center magnet
4 Detection object
5 Transport direction
6 Magnetic body
7 Reverse-transport magnetizing magnet
8 Magnetic bias vector
9 Magnetoresistive effect element chip
11 Magnetization magnetic field
14 Magnetization magnet
21 Bias magnetic field
31 Magnetization yoke
32 Biasing yoke
33 Magnetism-collecting yoke
34, 36, 38 Upstream-side yoke
35, 37, 39 Downstream-side yoke
51, 53 Magnetization magnet
61, 62 Magnetic body
91 Magnetoresistive effect element
100 Housing
101 Shield cover
311, 411, 511, 611, 711 Magnetization magnetic field
321, 421, 521, 621, 711 Bias magnetic field
531, 771 Magnetization magnetic field
P Transport plane

1. A magnetic sensor device for sensing a sheet-like detection object magnetized by a magnetizing magnet that forms a magnetization magnetic field in a transport plane, magnitude of a magnetic field component parallel to the transport plane in the transport plane of the magnetization magnetic field being larger than or equal to a saturation magnetic field of a second magnetic body having a second coercivity larger than a first coercivity, the magnetic sensor device comprising:
a bias magnet to form a bias magnetic field having a magnetic force direction of a center of a magnetic flux that intersects a plane of the detection object magnetized by the magnetizing magnet transported along the transport plane, wherein magnitude of a magnetic field component parallel to the plane of the detection object in the bias magnetic field occurring in the plane of the detection object is larger than the first coercivity, and is less than the second coercivity; and
a magnetoresistive effect element disposed at the bias magnet and facing the plane of the detection object,
wherein the bias magnetic field has, in a plane parallel to the transport plane, (i) a positive-direction component magnetic field that is directed in the same direction as a transport direction in which the detection object is transported, and (ii) a negative-direction component magnetic field that is directed opposite to the transport direction, and
upon the detection object passing through the bias magnetic field, (i) for a first magnetic body having the first coercivity, a direction of magnetization of the first magnetic body reverses, and (ii) for the second magnetic body having the second coercivity, a direction of magnetization of the second magnetic body remains the same as that of magnetization of the second magnetic body by the magnetizing magnet.

2. The magnetic sensor device according to claim 1, further comprising:
a center magnet disposed at one side of the transport plane, and having magnetic poles that are mutually different in a transport direction of transport of the detection object;
a first yoke disposed at an upstream side in the transport direction relative to the center magnet, the first yoke forming the magnetizing magnet; and
a second yoke disposed at a downstream side in the transport direction relative to the center magnet, the second yoke forming the bias magnet.

3. The magnetic sensor device according to claim 2, wherein a distance to the transport plane from a surface of the first yoke facing the transport plane is smaller than a distance to the transport plane from a surface of the second yoke facing the transport plane.

4. The magnetic sensor device according to claim 2, wherein
a length in the transport direction of the surface of the second yoke facing the transport plane is longer than a length in the transport direction of the surface of the first yoke facing the transport plane.

5. The magnetic sensor device according to claim 1, wherein the magnetizing magnet comprises:
a magnetization magnet having magnetic poles that are mutually different in a direction perpendicular to the transport plane; and
a magnetism-collecting yoke disposed at a surface on a transport plane side of the magnetization magnet, the magnetism-collecting yoke having a length in the transport direction of transport of the detection object that is smaller than a length in the transport direction of the magnetization magnet.

6. The magnetic sensor device according to claim 1, wherein the magnetizing magnet comprises:
a magnetization magnet having magnetic poles that are mutually different in the transport direction along which the detection object is transported; and
an upstream-side yoke disposed at an upstream side of the magnetization magnet in the transport direction; and
a downstream-side yoke disposed at a downstream side of the magnetization magnet in the transport direction.

7. The magnetic sensor device according to claim 6, wherein
at the transport plane side of the magnetization magnet, a proximate portion is formed in the upstream-side yoke, and a proximate portion is formed in the downstream-side yoke, and the proximate portions project so as to approach each other more closely than a transport direction length of the magnetization magnet.

8. The magnetic sensor device according to claim 1, further comprising:
a reverse-transport magnetizing magnet to form a second magnetization magnetic field in the transport plane at a downstream side of the bias magnet in the transport direction of transport of the detection object, magnitude of a magnetic field component of the second magnetization magnetic field parallel to the transport plane in the transport plane being larger than or equal to the saturation magnetic field of the second magnetic body.

9. The magnetic sensor device according to claim 8, wherein at least one of the magnetizing magnet or the reverse-transport magnetizing magnet comprises:
a magnetization magnet having magnetic poles that are mutually different in a direction perpendicular to the transport plane; and
a magnetism-collecting yoke disposed at a surface on a transport plane side of the magnetization magnet, the magnetism-collecting yoke having a length in the transport direction is smaller than a length in the transport direction length of the magnetization magnet.

10. The magnetic sensor device according to claim 8, wherein each of the magnetizing magnet and the reverse-transport magnetizing magnet comprises:
a magnetization magnet having magnetic poles that are mutually different in the transport direction;
an upstream-side yoke disposed at a transport direction upstream side of the magnetization magnet; and
a downstream-side yoke disposed at a transport direction downstream side of the magnetization magnet.

11. The magnetic sensor device according to claim 3, wherein
a length in the transport direction of the surface of the second yoke facing the transport plane is longer than a length in the transport direction of the surface of the first yoke facing the transport plane.

12. A magnetic sensor device for sensing a sheet-like detection object magnetized by a magnetizing magnet that forms a magnetization magnetic field in a transport plane, magnitude of a magnetic field component parallel to the transport plane in the transport plane of the magnetization magnetic field being larger than or equal to a saturation magnetic field of a second magnetic body having a second coercivity larger than a first coercivity, the magnetic sensor device comprising:
a bias magnet to form a bias magnetic field having a magnetic force direction of a center of a magnetic flux that intersects a plane of the detection object magnetized by the magnetizing magnet transported along the transport plane, wherein magnitude of a magnetic field component parallel to the plane of the detection object in the bias magnetic field occurring in the plane of the detection object is larger than the first coercivity, and is less than the second coercivity;
a magnetoresistive effect element disposed at the bias magnet and facing the plane of the detection object;
a center magnet disposed at one side of the transport plane, and having magnetic poles that are mutually different in a transport direction of transport of the detection object;
a first yoke disposed at an upstream side in the transport direction relative to the center magnet, the first yoke forming the magnetizing magnet; and
a second yoke disposed at a downstream side in the transport direction relative to the center magnet, the second yoke forming the bias magnet.

13. The magnetic sensor device according to claim 12, wherein a distance to the transport plane from a surface of the first yoke facing the transport plane is smaller than a distance to the transport plane from a surface of the second yoke facing the transport plane.

14. The magnetic sensor device according to claim 12, wherein
a length in the transport direction of the surface of the second yoke facing the transport plane is longer than a length in the transport direction of the surface of the first yoke facing the transport plane.

15. The magnetic sensor device according to claim 13, wherein
a length in the transport direction of the surface of the second yoke facing the transport plane is longer than a length in the transport direction of the surface of the first yoke facing the transport plane.
